(19) United States
(12) Patent Application Publication
(10) Pub. No.: US 2014/0150850 A1
(43) Pub. Date: Jun. 5, 2014

(54) SOLAR CELL COATING

(71) Applicant: AMTECH SYSTEMS, INC., Tempe, AZ (US)

(72) Inventor: Jeong-Mo Hwang, Phoenix, AZ (US)

(73) Assignee: Amtech Systems, Inc., Tempe, AZ (US)

(21) Appl. No.: 13/690,954

(22) Filed: Nov. 30, 2012

(51) Int. Cl. H01L 31/048

(52) U.S. Cl. CPC H01L 31/048
USPC 136/251

(57) ABSTRACT

Embodiments of the present invention help prevent Potential-Induced Degradation (PID) in solar cell modules. A solar cell module according to one embodiment of the present invention comprises a glass sheet, a frame covering at least a portion of the glass sheet, a plurality of solar cells at least partially covered by the glass sheet, and a hydrophobic coating covering at least a portion of the frame and at least a portion of the glass sheet.

### DETAILED DESCRIPTION OF THE INVENTION

1. Field of the Invention

The present disclosure relates to hydrophobic coatings for solar cell modules.

2. Background of the Invention

Solar cells (also known as photovoltaic cells) convert light energy into electricity. In many applications, solar cells are grouped together into modules to produce different voltage outputs. For example, some modules include 72 individual cells (in a 6×12 matrix) with each cell producing about 0.6V for a total output of about 40V per module. Other modules may include more or fewer cells and/or may produce more or less voltage. Such modules are often held together by a metallic (e.g., aluminum) frame and covered by a sheet of glass to protect the cells from water and debris. The frame is typically grounded for safety purposes. Some solar power-generation systems typically include about 25 modules which are connected in series. The cells in the far end module of such systems may reach a potential greater than 1,000V from the ground/reference potential.

Solar cell modules are typically located outdoors and are thus exposed to moisture from sources such as the humidity in the air, rain, or dew. When the protective glass sheet becomes wet while the solar module is generating electricity, a phenomenon known as Potential-Induced Degradation (PID) may occur. PID involves moisture on the module's glass sheet contacting the grounded frame, creating an electric field between the glass and the solar cells and directing impurities (such as sodium ions in the glass) into the solar cells, degrading their efficiency. Repeated instances of PID can permanently degrade the efficiency of solar modules. Embodiments of the present invention address these and other issues.

### SUMMARY OF THE INVENTION

Among other things, embodiments of the present invention help prevent Potential-Induced Degradation (PID) in solar cell modules. A solar cell module according to one embodiment of the present invention comprises a glass sheet, a frame covering at least a portion of the glass sheet, a plurality of solar cells at least partially covered by the glass sheet, and a hydrophobic coating covering at least a portion of the frame and at least a portion of the glass sheet.

### DESCRIPTION OF THE DRAWINGS

FIG. 1A illustrates a solar cell module according to various aspects of the present invention.

FIG. 1B is an exploded perspective view of the solar cell module in FIG. 1A.

FIG. 2 is a side cutaway view of the solar cell module in FIG. 1A.

FIG. 3 illustrates PID in conjunction with the solar cell module in FIG. 1A.

FIGS. 4A-4C illustrate exemplary hydrophobic coatings that may be used in conjunction with the solar cell module in FIG. 1A.

### DETAILED DESCRIPTION OF PREFERRED EMBODIMENTS

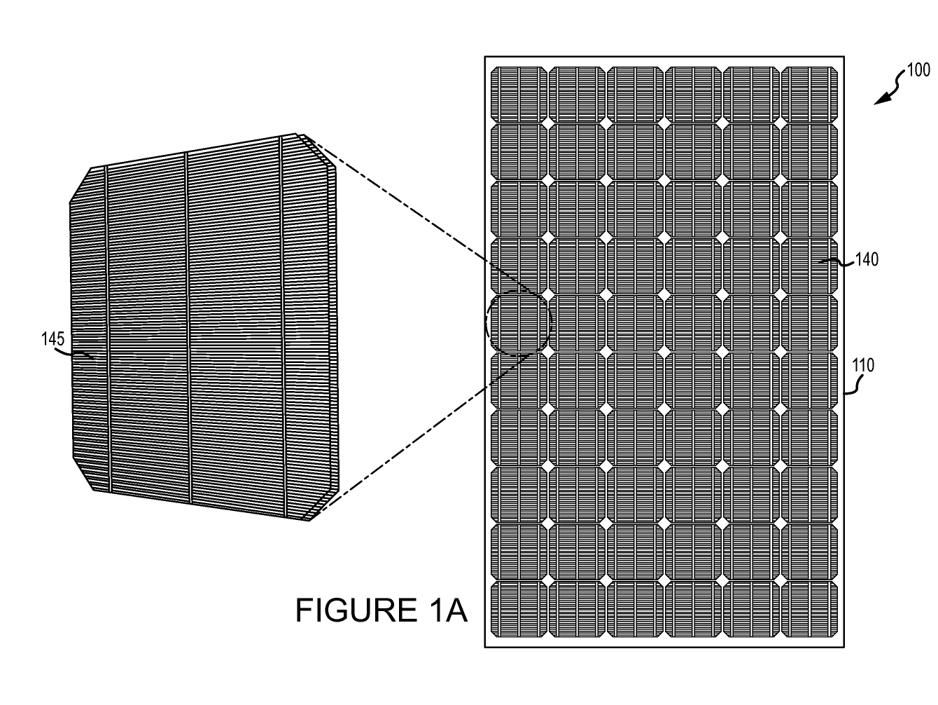

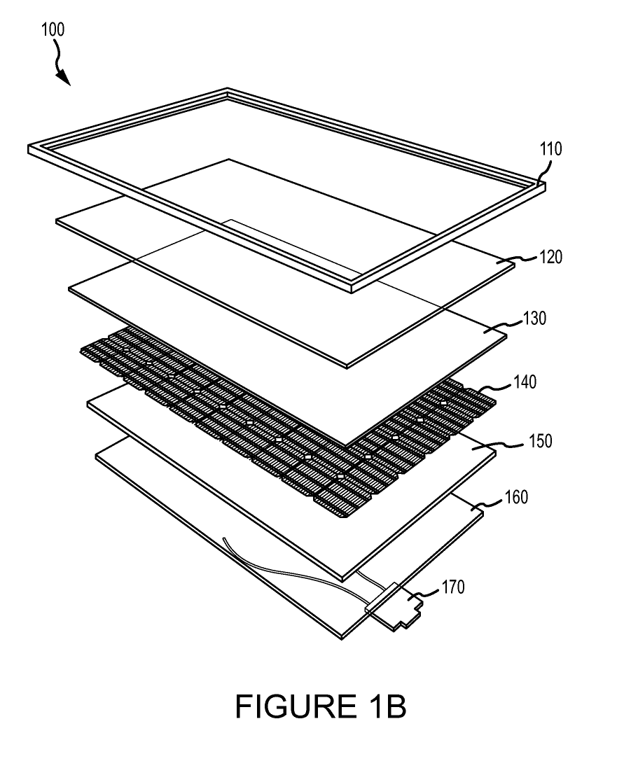

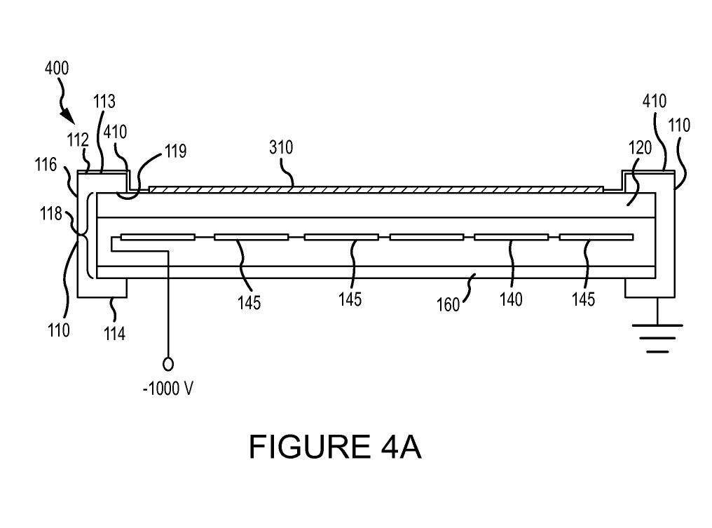

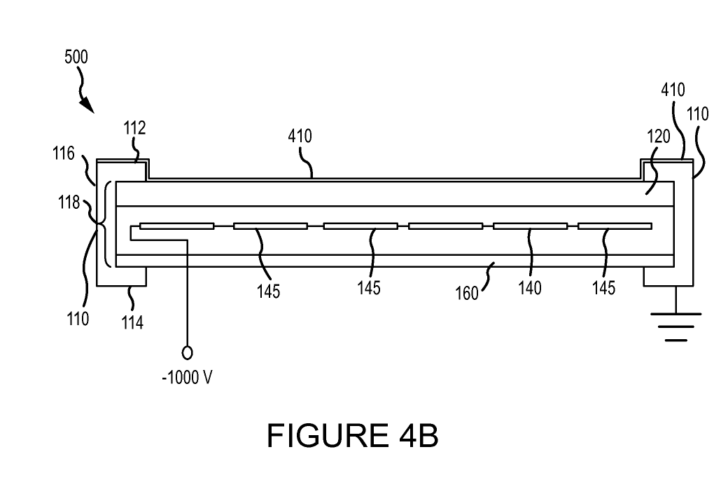

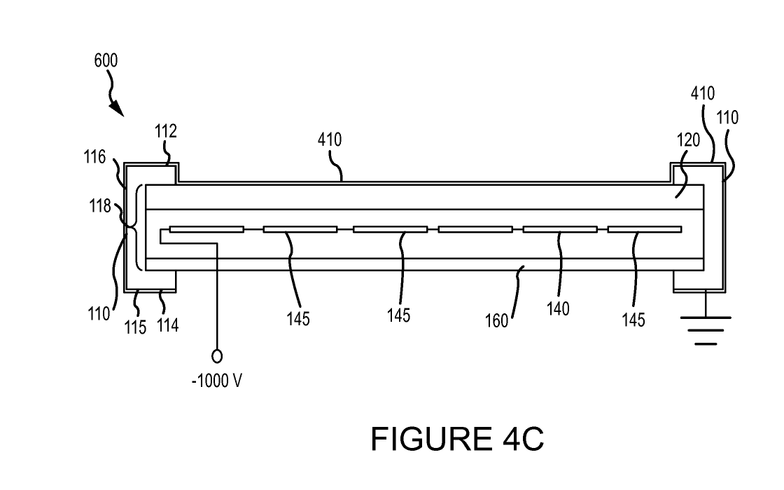

FIGS. 1A and 1B depict an exemplary solar cell module according to various aspects of the present invention. Solar cell module 100 includes a group of 72 individual solar cells 145 electrically connected together into a single sheet of cells 140. The solar cell sheet 140 is disposed between a pair of encapsulation sheets 130, 150. A sheet of glass 120 covers the top encapsulation sheet 130, while an insulating back sheet 160 is disposed beneath the bottom encapsulation sheet 150. The layers of the solar cell module 100 (i.e., layers 120-160) are held together (at least in part) by a frame 110. Module 100 also includes a junction box 170 for electrically coupling the solar cell module 100 to one or more additional solar cell modules (e.g., in an array of modules). As discussed in more detail with reference to FIGS. 4A-4C, the solar cell module 100 may include a hydrophobic coating (not shown) to help prevent PID from occurring when the glass sheet 120 is exposed to moisture.

The frame 110 surrounds the layers (120-160) of the module 100. In some embodiments, the frame 110 is formed from an electrically conductive material, such as aluminum or another metal. In such embodiments, the frame may be coupled to electrical ground, and the solar cells 140 may be electrically coupled to, and grounded via, the frame. Among other things, this helps reduce the risk of shock to anyone handling the module 100. The frame 110 may be formed from any other desired material(s).

The glass sheet 120 protects the components of the module 100 from wind, dust, moisture, and other environmental effects while allowing light to pass through to the solar cells 140. The glass sheet 120 may be formed from plate or tempered glass, as well as transparent plastics (such as methyl methacrylate).

The encapsulation sheets 130, 150 encapsulate the solar cells 140 to protect them from physical damage or exposure to moisture (which can corrode electrical contacts on the cells). The encapsulation sheets 130, 150 may be formed from any suitable materials, including ethylene-vinyl acetate (EVA).

The solar cell layer 140 comprises a group of individual solar cells 145 electrically coupled together to produce electricity from light energy. In exemplary module 100, the solar cell layer 140 includes 72 total cells arranged in six columns of twelve cells.

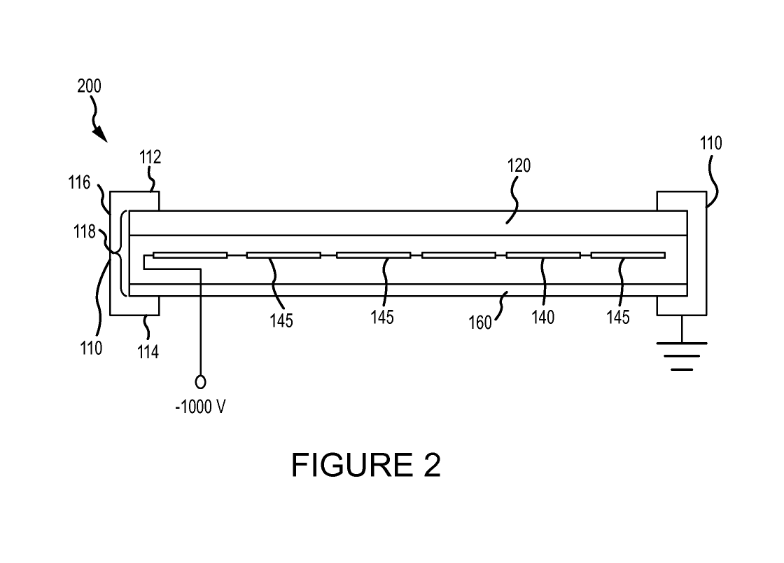

FIG. 2 is a side cutaway view of module 100 showing the six columns of cells 145 in solar cell layer 140. The frame 110 includes a top portion 112, bottom portion 114, exterior sidewall 116, and a channel 118 formed therebetween for receiving the glass sheet 120 and other layers of the solar cell module 100. Assuming the corresponding module is the last one in a solar system unit which consists of about 25 modules connected in series, as illustrated in this figure, the voltage difference between the left-most cell 145 and the ground (GND) terminal is about 1000V (−1000V for p-type solar cells as shown here, or +1000V for n-type solar cells), assuming a light intensity of air mass (AM) 1.5. When the glass sheet 120 is dry, it acts as an insulator, therefore inhibiting electrical coupling between the glass sheet 120 and aluminum frame 110.

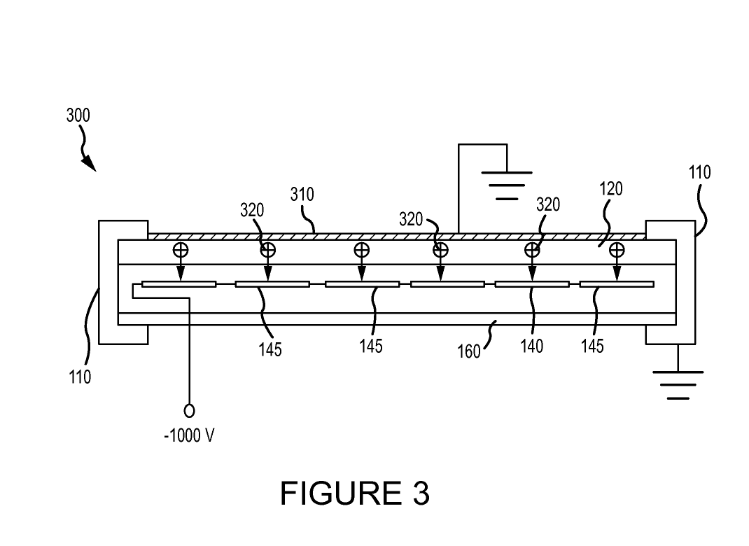

As shown in FIG. 3, however, water 310 on the glass 120 and frame 110 (while there is still enough light intensity for the solar cells 140 to generate electricity), can cause PID. The layer of water 310 on the surface of the glass sheet 120 contacts the frame 110, grounding the top surface of the glass 120 and forming a high (−1000V) electric field between the top surface of the glass 120 and the solar cells 140. This high-voltage field can push impurity ions residing in the glass 120 into the solar cells 140, potentially penetrating the individual cells 145 and disrupting their efficiency (PID). Repeated instances of PID can permanently degrade the efficiency of the solar cells 140.

Embodiments of the present invention can help prevent degradation of the solar cell layer 140 by PID. In one embodiment, referring now to FIG. 4A, solar cell module 400 includes a hydrophobic coating 410 covering at least a portion of the frame 110 and at least a portion of the glass sheet 120. Among other things, the hydrophobic coating 410 helps prevent the water 310 on the surface of the glass 120 from electrically connecting with the grounded frame 110, thereby helping to prevent the formation of an electric field between the surface of the glass 120 and the solar cell layer 140. In this embodiment, the hydrophobic coating covers the top surface 113 of the top portion 112 of frame 110, as well as a portion of the glass sheet 120, and the joint 119 between the frame 110 and the glass sheet 120. The hydrophobic coating 410 may also help to protect the frame 110 and seal the interior of the module 400 from moisture and dirt. Coating just a portion of the glass 120 as shown in FIG. 4A can help reduce the cost of the module 100 (e.g., by using less hydrophobic material) and helps to avoid the coating 410 from obstructing light from reaching the solar cells 140.

Any desired hydrophobic coating may be used in conjunction with embodiments of the present invention. Coatings used in conjunction with embodiments of the present invention may also be applied to portions of a solar cell module in any suitable manner, including vapor deposition, spraying, brush-coating, dip-coating, spin-coating, and/or inkjet printing.

In cases where the hydrophobic coating is at least partially transparent, some embodiments of the present invention may coat the entire top surface of the glass sheet 120. Referring now to FIG. 4B, module 500 includes a hydrophobic coating 410 that covers the top surface 112 of the frame 110 as well as the entire top surface of the glass sheet 120. In this exemplary embodiment, the coating 410 will help repel moisture contacting any portion of the top surface of module 500. The coating 410 for module 500 may also be easier and more cost-effective to apply using vapor deposition, spraying, or other methods of application.

The hydrophobic coating may coat any portion(s) of a solar cell module. In FIG. 4C, for example, the hydrophobic coating 410 of module 600 covers the top surface of the glass sheet 120, and the top surface 112, exterior sidewalls 116, and bottom surface 115 of frame 110. The hydrophobic coating configurations described in FIGS. 4A-4C can be used in conjunction with other types and configurations of solar modules as well. For example, any of the above-described coatings may be used with solar cell modules having fewer or more components than those in module 100.

The particular implementations shown and described above are illustrative of the invention and its best mode and are not intended to otherwise limit the scope of the present invention in any way. Indeed, for the sake of brevity, conventional data storage, data transmission, and other functional aspects of the systems may not be described in detail. Methods illustrated in the various figures may include more, fewer, or other steps. Additionally, steps may be performed in any suitable order without departing from the scope of the invention. Furthermore, the connecting lines shown in the various figures are intended to represent exemplary functional relationships and/or physical couplings between the various elements. Many alternative or additional functional relationships or physical connections may be present in a practical system.

Changes and modifications may be made to the disclosed embodiments without departing from the scope of the present invention. These and other changes or modifications are intended to be included within the scope of the present invention, as expressed in the following claims.

What is claimed is:

1. A solar cell module comprising:
a glass sheet;
a frame covering at least a portion of the glass sheet;
a plurality of solar cells at least partially covered by the glass sheet; and
a hydrophobic coating covering at least a portion of the frame and at least a portion of the glass sheet.

2. The solar cell module of claim 1, wherein the frame is electrically conductive and coupled to electrical ground.

3. The solar cell module of claim 1, wherein the frame includes:
a top portion;
a bottom portion;
an exterior sidewall; and
a channel formed by top portion, the bottom portion, and the exterior sidewall, wherein the glass sheet is received in the channel.

4. The solar cell module of claim 3, wherein the top portion of the frame includes a top surface, wherein the hydrophobic coating covers the top surface of the frame and a portion of the glass sheet.

5. The solar cell module of claim 4, wherein the hydrophobic coating covers a joint between the top surface of the frame and the glass sheet.

6. The solar cell module of claim 3, wherein the hydrophobic coating covers the entire top surface of the glass sheet.

7. The solar cell module of claim 3, wherein the hydrophobic coating further covers the exterior sidewall.

8. The solar cell module of claim 3, wherein bottom portion of the frame includes a bottom surface, and wherein the hydrophobic coating further covers the bottom surface of the frame.

9. The solar cell module of claim 1, whereby the hydrophobic coating insulates the glass sheet from the frame and prevents formation of an electric field between the glass sheet and the plurality of solar cells when the glass sheet is exposed to moisture.

10. The solar cell module of claim 1, wherein the hydrophobic coating is applied to the solar cell module using one or more of the group consisting of: vapor deposition, spraying, brush-coating, dip-coating, spin-coating, and inkjet printing.
